(19) United States
(12) Patent Application Publication
(10) Pub. No.: US 2004/0116152 A1
(43) Pub. Date: Jun. 17, 2004

(54) Dual-mode transmitter

(76) Inventors: Basim Noori, Folsom, CA (US); Jaspal Bharj, Middlesex (GB); Martin Goss, Berkshire (GB)

Correspondence Address: SQUIRE, SANDERS & DEMPSEY L.L.P., 14TH FLOOR, 8000 TOWERS CRESCENT, TYSONS CORNER, VA, 22182, US

(21) Appl. No.: 10/472,262

(22) PCT Filed: Mar. 21, 2002
(86) PCT No.: PCT/IB02/00886

(30) Foreign Application Priority Data
Mar. 22, 2001 (GB) 0107264.4

(51) Int. Cl. H04B 1/02; H04B 1/66; H03F 3/04

(52) U.S. Cl. 455/552.1; 455/93; 455/102; 330/297

(57) ABSTRACT

A method and circuitry for a transmitter is disclosed. The transmitter is adapted for transmission of signals based on at least two different transmission modes. In the method a signal to be transmitted in accordance with a selected transmission mode is input in a single path (1) comprising amplifier means (10). Based on the selected transmission mode, the waveform of the signal is shaped by combining at least two waveforms. The mode of at least one component on the signal path is switched between said at least two transmission modes by means of a switching circuit (50).

### FIELD OF THE INVENTION

The present invention relates to transmission of signals, and in particular, but not exclusively, to processing of signals to be transmitted from a multimode transmitter.

### BACKGROUND OF THE INVENTION

A transmitter can be used in a communication system for provision of communication media towards other nodes of the communication system. The other nodes may comprise user terminals, different exchanges, switches, routers and so on. The communication may be transmitted as analogue or digital signals or a combination of these, such as by digitally-modulated analogue signals.

Signal amplification is required in various communication applications. For example, radio frequency signals transmitted in a radio communication system may need to be amplified during some stage of the transmission and/or reception. The amplification of the signals may be required because the amplitude of a signal tends to be attenuated during the transmission of the signal. This may decrease the quality of the transmission. Also, noise is typically added to the signal from the elements on the signal path, such as from the transmitting and receiving apparatus and/or any possible intermediate apparatus. A communication system may thus be provided with amplifying means to compensate for the attenuation and increase the signal-to-noise ratio of the signal by amplification of the signal.

Amplifiers that are intended to cover a range of frequencies should provide substantially linear performance across the designated frequency band. However, any amplifier introduces linear, or AM-PM (amplitude modulation—phase modulation) distortion, where amplitude variations in the input signal cause undesirable phase variations in the output signal. In addition, the signals may also become subject of intermodulation. The intermodulation may cause mixing between the different frequency components present.

In a digital communication system, power amplifiers are a source of substantial distortion due to their inherent non-linear characteristics. The non-linear characteristics introduce undesired non-fundamental spectral components on either side of the desired carrier. This phenomenon is known as spectral regrowth. The spectral regrowth has recently become even more pronounced with the introduction of linear digital modulation schemes such as the π/4-DQPSK (differential quadrature phase shift keying) and, perhaps more importantly, the 3π/8-8PSK. This is due to the requirement for as efficient use of the frequency spectrum as possible. From these two digital modulation schemes the latter is a variant of the first mentioned.

Non-linearity is a term used to describe the degree of resemblance of the output to the input of an amplifying device. Under large signal conditions all radio Frequency (RF) amplifiers are eventually non-linear, and hence they can be described using a power series expansion of the form:

y(t)=g₁x(t)+g₂x(t)²+g₃x(t)³+. . . (1)

where y(t) represents the time-varying output signal, and coefficients gᵢ are constants and describe the transfer characteristics of the amplifier (the first, second and third-order coefficients of the transfer function respectively).

Due to mixing inside the non-linear devices, when two carriers f1 and f2 are injected i.e. input into a power amplifier, the 3^{rd} order products of equation (1) appear in the form of intermodulation distortion (IMD). The 3^{rd} order products are equal to 2f1-f2 & 2f2-f1 which generally lie inside the operating band. The effect of the IMD is shown by the graph of FIG. 1. The effect can be seen as worsening spectral regrowth as the non-linearity increases.

The 3^{rd} order products become even more complex as the number of carriers increases, eventually becoming a virtual noise floor. One way of analysing a digital phase modulated signal is to look at it as two individual carriers, having the same frequency and 90 degrees out of phase. In fact, it is slightly more complicated in the sense that a single harmonic component in the frequency domain translates into the time domain as a single ideal signal source switched on from a minus infinity to a plus infinity. In other words, if the source is switched off, attenuated or modulated, then several frequency domain components will appear. Consequently, at least in theory, the 3^{rd} order IMD products will depend on all these components. In practice however, it has been shown that techniques such as second harmonic cancellation and predistortion may be performed adequately without the need to analyse, extract or measure these complex products.

One relatively straightforward solution to linearise an amplifier is the so called backing off. The backing off exploits the fact that the non-linearity increases with the output power level of the amplifier. More particularly, in accordance with this technique the amplifier is backed off from a selected point on the power input/output curve towards the linear region. Thus, if the input level is reduced, i.e. “backed-off”, the amplifier is “limited” to operate only within its more linear region. The selected point typically substantially corresponds the so called P1dB point. The P1dB point is a figure of merit. The P1dB point defines a point at which the difference between the ideal linear input/output curve and in the real input/output curve is 1 dB. However, this approach fails to utilise the full range of available output voltage-swing and is therefore not especially efficient. A typical back off is in the region of 5-10 dB at the expense of efficiency of the amplifier.

Some communication systems require substantially high linearity from the power amplifier (PA). An example of such systems is a system that is based on the EDGE (Enhanced Data Rate for GSM Evolution) standard. The requirement for the high linearity is due to the linear modulation scheme used for the communication (e.g. the 3π/8-8PSK).

The EDGE has evolved from the GSM (Global System for Mobile communications). Therefore the characteristics of an EDGE based system require that the amplifier needs to be back compatible with the GSM system transmission mode. In the GSM mode the linearity is not that essential requirement. Instead, the GSM mode requires a substantially high efficiency.

In other words, the EDGE mode requires relatively high linearity from the power amplifier of the transmitter whereas the GSM mode typically requires relatively low linearity or no linearity at all from the power amplifier. Instead, the GSM mode requires typically relatively high efficiency from the power amplifier. The high linearity required by the EDGE mode may be achieved by the backing-off or predistortion techniques. However, the linearity is obtained at the expense of efficiency. Due to the different requirements separate amplifier circuits have been implemented in the prior art multimode transmitters.

Some prior art amplifier arrangements that enable multi-mode operation produce a substantial amount of heat. The performance of the amplifier arrangements may need to be limited to avoid problems caused by the overheating. In addition, some prior art arrangements may require a communication media between biasing means of the transmitter and waveform generators.

What is needed is an amplifier arrangement for a transmitter that may be used for more than one transmission mode.

### SUMMARY OF THE INVENTION

It is therefore the aim of the present invention to address one or several of the drawbacks of the prior art arrangements.

According to one aspect of the present invention, there is provided a method in a transmitter for transmission of signals based on at least two different transmission modes, the method comprising: inputting a signal to be transmitted in accordance with a selected transmission mode in a signal path comprising amplifier means; based on the selected transmission mode, shaping the waveform of the signal that is to be output from the signal path by combining at least two waveforms; and switching the mode of at least one component on the signal path between said at least two transmission modes.

In a more specific embodiments a linear output waveform or an efficient output waveform is produced by shaping the waveform. The switching may be provided by means of a variable biasing circuit. The switching may be accomplished for enhancing the efficiency of a transmission mode. During the switching a variable biasing circuit may alter gate and/or drain voltage and/or current.

Several harmonic waveforms can be mixed to produce a square-like waveform. Different types of waveforms may be combined. Multiplies of at least one waveform may be combined. Variants of at least one waveform may be combined.

The transmission mode that is to be used for the transmission may be determined. An output waveform may then be adaptively produced based on said determination. The signal path may be switched between at least two different modes on slot by slot basis.

The switching may be controlled based on a control signal derived from the baseband of the signal. The control signal may comprise a DC control signal.

According to another aspect of the present invention there is provided circuitry for a multimode transmitter, comprising: amplifier means for amplifying signals; means for shaping the output waveform of the circuitry, said shaping being adapted to be accomplished based on a selected transmission mode by combining at least two waveforms; and switching circuit for switching the mode of operation of he circuitry between at least two transmission modes.

The circuitry can be embodied in a station of a cellular communication system comprising. The cellular communication system may be adapted for communication in accordance with at least one of the following modes: a GSM transmission mode; an enhanced data rate for GSM evolution transmission mode; a code division multiple access transmission mode.

The embodiments of the invention may improve the efficiency of an amplifier. An amplifier may be arranged to switch between two waveforms without change in the configuration of the amplification circuitry. An amplifier may be arranged to switch adaptively between two different waveforms. For example, the waveform generated for the signal may be switched between a linear output waveform and an efficient output waveform. A single amplifying circuitry may be used for two different transmission modes (for example, both for the GSM mode and the EDGE mode and so on) requiring different characteristics from the amplifier. For example, the amplifier may be arrange to operate a harsh time slot-by-time slot mode such that it switched arbitrarily between the GSM and EDGE modes. The disclosed amplifier may produce less heat that the prior art amplifier arrangements. Thus the thermal limitations may be more relaxed than in the prior art arrangements.

### BRIEF DESCRIPTION OF DRAWINGS

For better understanding of the present invention, reference will now be made by way of example to the accompanying drawings in which:

FIG. 1 is a diagram illustrating spectral growth;

FIG. 2 shows a radio communication arrangement in which the embodiments of the invention may be employed;

FIG. 3 shows circuitry in accordance with an embodiment of the present invention;

FIG. 4a shows a set of harmonically related individual waveforms and FIG. 4b shows the resultant output waveform after the harmonically related waveforms have been combined;

FIG. 5 shows individual harmonics components;

FIG. 6 shows a resultant efficient waveform obtained by combining the harmonic components of FIG. 5;

FIG. 7 shows a linear output waveform; and

FIG. 8 is a flowchart illustrating the operation of one embodiment of the present invention.

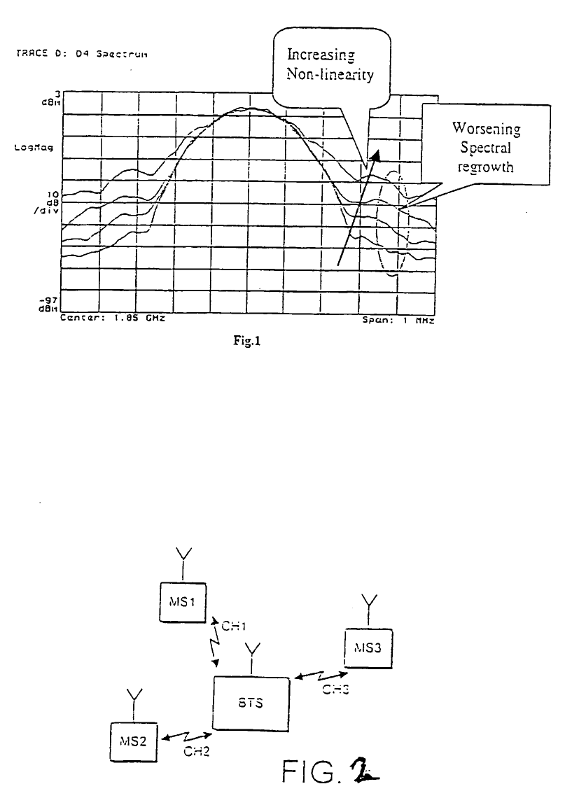

### DESCRIPTION OF PREFERRED EMBODIMENTS OF THE INVENTION

Reference will be first made to FIG. 2 illustrating a system in which the embodiments of the invention may be employed. The exemplifying system is a cellular mobile radio communication system allowing a plurality of mobile stations MS1, MS2, MS3 to communicate with a base (transceiver) station BTS via respective channels CH1, CH2, CH3. The channels can be established over respective air interfaces. An air interface as such is known, and will not be described in more detail herein. The stations are provided with necessary transceiver components (not shown in FIG. 2) so as to be able to handle signals to be transmitted and received by respective antennae. These components are also known to a skilled person and do not as such form a part of the invention, and are thus not described in more detail. It is sufficient to note that a station typically include one or several power amplifiers.

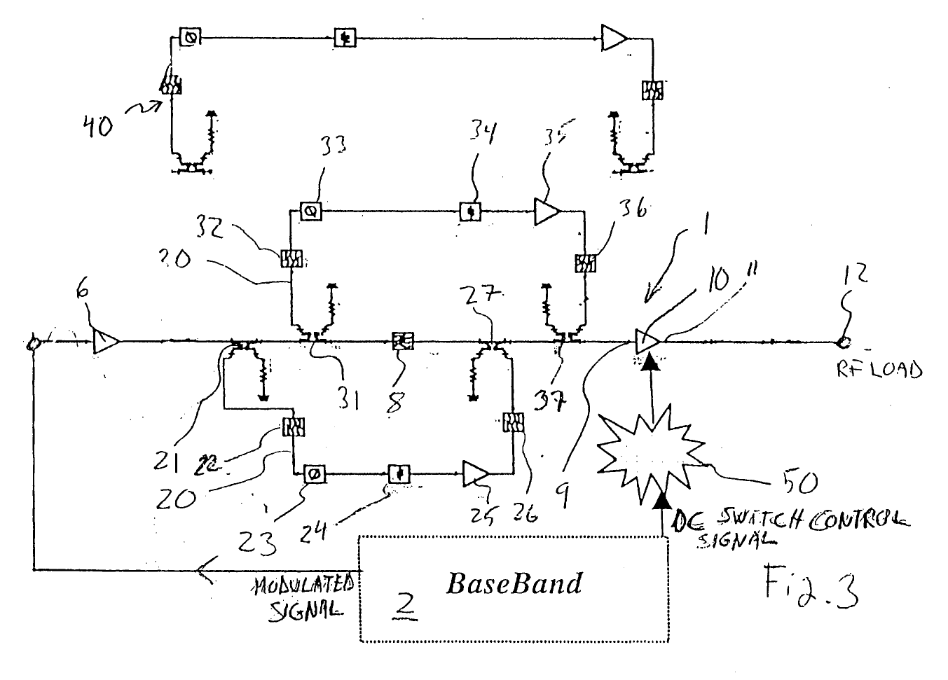

FIG. 3 illustrates possible power amplifier circuitry that may be used e.g. in the base station BTS of FIG. 2. The circuitry comprises a power amplifier 10 on a signal path 1. The circuitry of FIG. 3 may be arranged to operate in two different modes. In the herein described example the modes are the GSM mode and the EDGE (enhanced data rate for GSM evolution) mode.

The multi-carrier EDGE mode requires relatively high linearity from the power amplifier of the transmitter whereas the single carrier GSM mode typically requires relatively low linearity. Instead, the GSM mode requires a relatively high efficiency from the power amplifier. The FIG. 3 circuitry is adapted to enable ‘engineering’ i.e. shaping of the waveform that is input to amplifier means 10 such that a desired output waveform can be produced. By means of the engineering or shaping process the waveform is preferably adapted during the time slot transition period so that the different requirements of linearity and efficiency of the different transmission modes can be met.

The signal path 1 of the FIG. 3 circuitry is adapted to receive a modulated signal from baseband 2. The skilled person is familiar with the ways to modulate the baseband signal. Therefore modulation means are not shown and operation thereof is not explained in more detail.

The signal path is shown to comprise an amplifier 6. The amplifier 6 is used as a driver amplifier and as a harmonic component generator.

An appropriate number of multi-harmonic predistortion means may be provided for producing a resultant waveform at the input of a final stage power amplifier 10. The purpose of said predistortion means is to improve the linearity of the main signal when output from the amplifier 10 by producing appropriate distortion in the input signal. The FIG. 3 circuitry is shown to be provided with two non-linear predistortion path means 20, 30. By means of the predistortion means the input signal is deliberately distorted prior to being inputted to the amplifier 10 in a manner that is contrary to that distortion the signal experiences in the amplifier. This results in cancellation of the distortion.

The predistortion circuitry is arranged such that the 2fo and 3fo distortion components can be produced independently from each other by the paths 20,30. That is, the second order and third order non-linear paths 20 and 30, respectively, may be operated such that they do not affect each other.

Each of the non-linear paths 20, 30 is preferably implemented in a substantially similar manner to those lineariser circuits known as feed-forward (F/F) linearisers. In such an arrangement an input signal consisting of two closely spaced tones is first sampled by a directional coupler 21 in a location before the amplifier 10. The samples may be filtered by a first filtering component 22. After filtering the samples may be passed through a phase-shifting component 23. The phase shifted predistortion signal may then be passed to an amplitude attenuation component 24.

After attenuation stage may be provided an amplification stage 25. The amplification stage 25 is for ensuring that an adequate harmonic level becomes injected into the main amplifier 10 of the signals path 1.

A second filtering component 26 may be provided on the signal path before a coupler 27 before input 9 of the amplifier 10. The first and second filtering components 22 and 26 form together the 2^{nd} harmonic filter of the circuitry. The coupler 27 provides a combiner between the 2fo oath 20 and the main signal path 1.

The components on each of the non-linear predistortion paths may be similar, and thus the corresponding components 31 to 37 of the 3fo path 30 will not be described in detail. It is sufficient to note that the filtering components 32 and 36 form together a 3^{rd} harmonic filter of the circuitry.

A filter 8 may be provided between inputs and outputs at the combiners 21,27 and 31,37 to provide isolation between the respective ends of the paths 20 and 30.

Although it is believed that in most applications it is adequate to provide predistortion paths only for the 2^{nd} and 3^{rd} order harmonics, any number of the predistortion paths may be provided. FIG. 3 illustrates a further nfo non-linear path 40. Any such further non-linear paths may also be operated correspondingly independently from the other non-linear paths.

The linearisation, however, causes losses in the efficiency of the amplifier. The linearisation may also produce a substantial amount of heat. To address these problems and to increase efficiency during the GSM mode a mode switching function is provided. The mode switching function is adapted to drive the amplifier 10 such that the amplifier gives a substantially linear output when the amplifier operates in the EDGE mode and a substantially high efficiency when the amplifier 10 operates in the GSM mode.

The switching function may be provided by means of a biasing network 50. The biasing network 50 is adapted to alter the gate and/or drain voltage (and/or current) in order to achieve optimum efficiency in the GSM mode. The skilled person is familiar with different biasing circuits and of the various possibilities for the circuit 50. Since the selection of an appropriate means for the switching function is an implementation issue the various possibilities are not explained in any great detail. It is sufficient to note that the circuit 50 may be based e.g. on P-MOS or N-MOS configuration or that the switching may be arranged to be controlled by a microprocessor or other processor means.

The switching function is typically provided with a switching control signal supply. In FIG. 3 the control signal comprises a DC switch control signal that is provided based on information from the baseband. The variable gates of the switching circuit 50 or similar switching elements may then be driven based on this signal. The term DC (direct current) is known by the skilled person and refers to the manner signals are transmitted in the GSM mode.

After the signal has been processed by the above described means on signal path 1 so as to shape the resultant waveform either a linear or an efficient output the signal is input into a load 12. The load 12 may be e.g. an antenna of a transmitter, a combining network and so on.

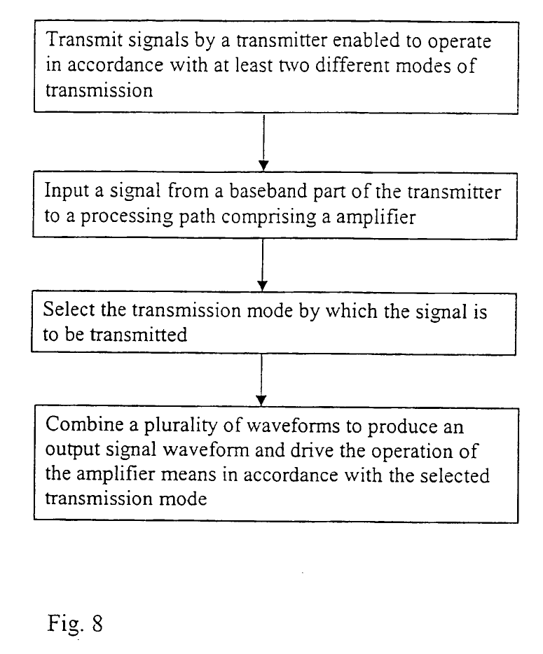

The following will describe, with a reference to the flowchart of FIG. 8 and FIGS. 4 to 7, a more detailed example of operation in accordance with an embodiment.

FIG. 4a shows several types of harmonically related individual waveforms. FIG. 4b shows a resultant waveform obtained by combining the seven individual harmonic components of FIG. 4a.

A waveform of a linear amplifier, when viewed in a time domain should appear as perfect sinusoid (see FIG. 7). As is shown by FIG. 6, a waveform of an efficient amplifier, however, should appear as a square wave. Multi-harmonic mixing as exemplified by FIGS. 4a and 4b may be used for achieving a square output waveform of FIG. 6 for the efficient part of the frame. The harmonic components for the mixing can be produced by the circuits 20 and 30 of FIG. 3. The components are mixed to achieve the linear mode operation in the EDGE mode (FIG. 7) and the efficient operation in the GSM mode (FIG. 6).

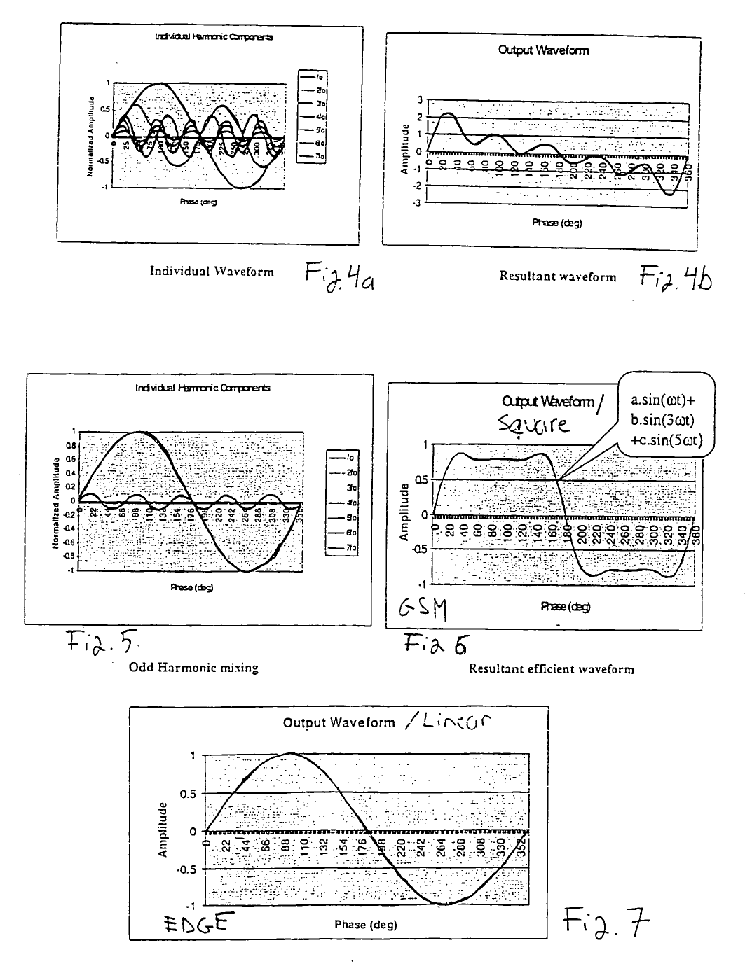

More particularly, FIG. 6 shows the resultant waveform when odd harmonic mixing of individual harmonic components of FIG. 5 is employed to produce a desired, resultant efficient output waveform. For example, 3^{rd} and 5^{th} order harmonics may be used to square the waveform. The 2^{nd} harmonic path 20 may operate to cancel out the 2^{nd} harmonics generated in the amplifier.

The efficiency of the GSM mode of the transmitter can be increased if the signal path is switched from the essentially linear EDGE mode to the GSM mode. The switching may be accomplished means of the variable biasing circuit 50 comprising variable gates. As explained above, the efficiency would have otherwise degraded in the GSM mode due to back-off conditions.

The efficiency of the GSM mode can be enhanced compared to what could be obtained by back off conditions. In this mode the 3^{rd} and 5^{th} harmonics may be utilised to square the waveform and the second harmonic path can the used to cancel out the 2^{nd} harmonics generated by the amplifier. When switched from the efficient, harmonically mixed waveform mode to a linear waveform the switching can be accomplished so that efficiency may also be maintained during the linear part of the frame.

The switching between different output waveforms is preferably arranged so that an adaptive multimode system is be provided.

More than one switching circuit may be provided. This may be required e.g. if the transmitter is indented to operate in accordance with three different modes (e.g. in accordance with the GSM, the EDGE and a CDMA mode).

The described embodiment facilitates use of a radio frequency (RF) power amplifier circuit for at least two different transmission modes. This is accomplished without any reconfiguration of the circuitry so that a desired waveform, i.e. either a linear output waveform or an efficient output waveform, may be produced by the same power amplifier circuitry.

Both analogue and digital predistortion can be for the linerisation. The predistortion systems may be constructed so as to form an open loop predistorter or a closed loop (i.e. adaptive) predistorter. The latter has the advantage of being able to adjust for device variations e.g. with respect to temperature and time.

It should be appreciated that whilst embodiments of the present invention have been described in relation to base stations and mobile stations, embodiments of the present invention are applicable to any other suitable type of radio equipment in which there is need to employ a power amplifier capable of operating in at least two different transmission modes.

The embodiment of the present invention has been described in the context of the GSM and EDGE systems. However, the radio communication between a transmitting station and a receiving station may be implemented in any appropriate manner and may be based on any communication standard. This invention is thus applicable to any access techniques such as those based on code division multiple access, frequency division multiple access, time division multiple access, space division multiple access as well as any hybrids thereof. Examples of the possible communication standards include, without being limited to these, AMPS (American Mobile Phone System), DAMPS (Digital AMPS), GSM (Global System for Mobile communications) or various GSM based systems (such as GPRS: General Packet Radio Service), CDMA (Code Division Multiple Access), IS-95 or any of the 3^{rd} generation (3G) communication systems, such as WCDMA (Wideband CDMA), UMTS (Universal Mobile Telecommunications System), IMT-2000 (International Mobile Telecommunications System 2000), i-phone and so on.

It is also noted herein that while the above describes exemplifying embodiments of the invention, there are several variations and modifications which may be made to the disclosed solution without departing from the scope of the present invention as defined in the appended claims.

1. A method in a transmitter for transmission of signals based on at least two different transmission modes, the method comprising:
inputting a signal to be transmitted in accordance with a selected transmission mode in a signal path comprising amplifier means;
based on the selected transmission mode, shaping the waveform of the signal that is to be output from the signal path by combining at least two waveforms; and
switching the mode of at least one component on the signal path between said at least two transmission modes.

2. A method according to claim 1, wherein a linear output waveform is produced by shaping the waveform.

3. A method as claimed in claim 1, wherein an efficient output waveform is produced by shaping of the waveform.

4. A method as claimed in any preceding claim, wherein the switching is provided by means of a variable biasing circuit.

5. A method as claimed in any preceding claim, wherein switching is accomplished for enhancing the efficiency of a transmission mode.

6. A method as claimed in claim 4 or 5, wherein the variable biasing circuit alters gate and/or drain voltage and/or current.

7. A method according to any of the preceding claims, wherein several harmonic waveforms are mixed to produce a square-like waveform.

8. A method according to any of preceding claims, wherein different types of waveforms are combined.

9. A method according to any of the preceding claims, wherein multiplies of at least one waveform are combined.

10. A method according to any of the preceding claims, wherein variants of at least one waveform are combined.

11. A method as claimed in any preceding claim, comprising a step for determining the transmission mode that is to be used for the transmission and adaptively producing an output waveform based on said determination.

12. A method according to claim 11, wherein the signal path is switched between at least two different modes on slot by slot basis.

13. A method as claimed in any preceding claim, wherein the switching is controlled based on a control signal derived from the baseband of the signal.

14. A method as claimed in claim 13, wherein the control signal comprises a DC control signal.

15. A method according to any of the preceding claims, wherein the amplifier comprises a power amplifier.

16. A method according to any of the preceding claims, wherein the communication system is a cellular telecommunication system.

17. A method according to claim 16, wherein the amplifier is for amplification of signals in a base station of the cellular telecommunications system.

18. A method according to any of the preceding claims, wherein the signal is input from the signal path into an antenna.

19. A method according to any of the preceding claims, wherein the transmission modes comprise at least one of the following list: a GSM transmission mode; an enhanced data rate for GSM evolution transmission mode; a code division multiple access transmission mode.

20. Circuitry for a multimode transmitter, comprising:
amplifier means for amplifying signals;
means for shaping the output waveform of the circuitry, said shaping being adapted to be accomplished based on a selected transmission mode by combining at least two waveforms; and
switching circuit for switching the mode of operation of he circuitry between at least two transmission modes.

21. Circuitry as claimed in claim 20, wherein the switching is adapted to occur between a linear output waveform and an efficient output waveform.

22. Circuitry as claimed in claim 20 or 21, wherein the shaping means are arranged to combine several harmonic waveforms to produce a square-like waveform.

23. Circuitry as claimed in any of claim 20 to 22, wherein the shaping means are arranged to combine multiplies of at least one waveform.

24. Circuitry as claimed in any of claim 20 to 23, wherein the shaping means are arranged to combine variants of at least one waveform.

25. Circuitry as claimed in any of claim 20 to 24, wherein the shaping means are arranged to combine different types of waveforms.

26. Circuitry as claimed in any of claim 20 to 25, wherein the shaping means comprise at least two predistortion circuits.

27. Circuitry as claimed in any of claim 20 to 26, wherein the switching circuit comprises a biasing circuit.

28. Circuitry as claimed in any of claims 20 to 27, wherein the switching circuit is responsive to a control signal from baseband means of the transmitter.

29. Circuitry as claimed in any of claims 20 to 28 being arranged to switch adaptively between at least two transmission modes.

30. A cellular communication system comprising circuitry as claimed in any of claims 20 to 29.

31. A cellular communication system as claimed in claim 30 being adapted for communication in accordance with at least one of the following modes: a GSM transmission mode; an enhanced data rate for GSM evolution transmission mode; a code division multiple access transmission mode.

32. A base station of a cellular communication system comprising circuitry as claimed in any of claims 20 to 29.
